(19) United States
(12) Patent Application Publication
(10) Pub. No.: US 2023/0062156 A1
(43) Pub. Date: Mar. 2, 2023

(54) RANDOM NUMBER GENERATOR CIRCUIT

(71) Applicant: CHANGXIN MEMORY TECHNOLOGIES, INC., Hefei City, Anhui (CN)

(72) Inventor: Xian FAN, Hefei City, Anhui (CN)

(21) Appl. No.: 17/438,433

(22) PCT Filed: Jun. 11, 2021
(86) PCT No.: PCT/CN2021/099839

§ 371 Date: Sep. 12, 2021

(30) Foreign Application Priority Data
Sep. 2, 2020 (CN) 202010911973.6

(51) Int. Cl. G06F 7/58; G06F 7/76

(52) U.S. Cl. CPC G06F 7/584; G06F 7/76; H03K 19/21

(57) ABSTRACT

Embodiments of the present disclosure provide a random number generator circuit, including: a random number generator, configured to output a plurality of first random numbers in each counting cycle; a control signal generation module, configured to receive a trigger signal and output control signals corresponding to different first random numbers based on the trigger signal; and a multi-select module, configured to receive the first random number and the control signal corresponding to the first random number, based on the control signal to adjust at least one bit position of the first random number, obtain a second random number, and output a plurality of the second random numbers.

### CROSS-REFERENCE TO RELATED APPLICATIONS

The present disclosure is a national stage entry of International Application No. PCT/CN2021/099839, filed on Jun. 11, 2021, which claims the priority to Chinese Patent Application 202010911973.6, titled “RANDOM NUMBER GENERATOR CIRCUIT”, filed to the State Intellectual Property Office of People's Republic of China on Sep. 2, 2020. The entire contents of International Application No. PCT/CN2021/099839 and Chinese Patent Application 202010911973.6 are incorporated herein by reference in their entireties.

### TECHNICAL FIELD

The embodiments of the present disclosure relate to, but are not limited to, a random number generator circuit.

### BACKGROUND

In this information age, information security issues have become a very critical part of information products. Whether an encryption module has good security performance has become one of the current focuses.

For the encryption module, in order to improve its security performance, it is necessary to provide random numbers with good randomness as seeds to form a pseudo-random number sequence. However, the randomness of random numbers generated by current random number generator circuits still needs to be improved.

### SUMMARY

The following is a summary of the subject matter detailed herein. This summary is not intended to limit the protection scope defined by the claims. Embodiments of the present disclosure provide a random number generator circuit, comprising: a random number generator, configured to output a plurality of first random numbers in each counting cycle; a control signal generation module, configured to receive a trigger signal and output control signals corresponding to different first random numbers based on the trigger signal; and a multi-select module, configured to receive the first random number and the control signal corresponding to the first random number, based on the control signal to adjust at least one bit position of the first random number, obtain a second random number, and output a plurality of the second random numbers.

After reading and understanding the drawings and detailed description, other aspects may be understood.

### BRIEF DESCRIPTION OF THE DRAWINGS

The accompanying drawings, which are incorporated in and form a part of this specification, illustrate embodiments of the present disclosure and explain, together with the description, the principles of embodiments of the present disclosure. In these drawings, similar reference numerals are configured to denote similar elements. The drawings to be described below are some, but not all, embodiments of the present disclosure. Other drawings may be obtained by a person of ordinary skill in the art in accordance with these drawings without paying any creative effort.

FIG. 1 shows seven different circuit structure diagrams;

FIG. 2 is a functional block diagram of a random number generator circuit according to an embodiment of the present disclosure;

FIG. 3 is a functional block diagram of a random number generator circuit according to another embodiment of the present disclosure;

FIG. 4 is a schematic circuit structure diagram of the random number generator of FIG. 3;

FIG. 5 is a schematic structure diagram of the multi-select module of FIG.

FIG. 6 is a schematic structure diagram of the control signal generation module of FIG. 4;

FIG. 7 is another schematic structure diagram of the control signal generation module of FIG. 4; and

FIG. 8 is still another schematic structure diagram of the control signal generation module of FIG. 4.

### DETAILED DESCRIPTION

To make the purposes, technical solutions and advantages of the embodiments of the present disclosure clearer, the technical solutions in the embodiments of the present disclosure will be described clearly and completely with reference to the drawings in the embodiments of the present disclosure. Apparently, the embodiments to be described are some, but not all, embodiments of the present disclosure. Based on the embodiments of the present disclosure, all other embodiments obtained by a person of ordinary skill in the art without paying any creative effort should be included in the protection scope of the present disclosure. It is to be noted that the embodiments of the present disclosure and features in the embodiments may be combined if not conflict.

It can be known from the background that the randomness of the random number generator circuit in the prior art still needs to be improved.

It is found by analysis that, although the current random number generator circuit has disordered the output, there is still a certain context between the front and rear numbers, and it is difficult to achieve true randomness. As an example, a linear feedback shift register (LFSR) is used as the random number generator circuit to generate 7-bit random numbers. For a fixed random number generator circuit, since the tap position is fixed, this random number generator circuit can generate only one random sequence. The sequence of the front and rear numbers within a counting period is fixed. A bit position that affects the next state is called a tap position.

If it is needed to generate multiple random sequences, multiple random number generator circuits are required, and the tap position of each random number generator circuit is different. For example, a 7-bit LFSR has seven different tap positions. Seven LFSRs with different tap positions may be designed to obtain seven random sequences. Each random sequence may generate 2⁷-1 random numbers. In this way, the randomness of random numbers is improved.

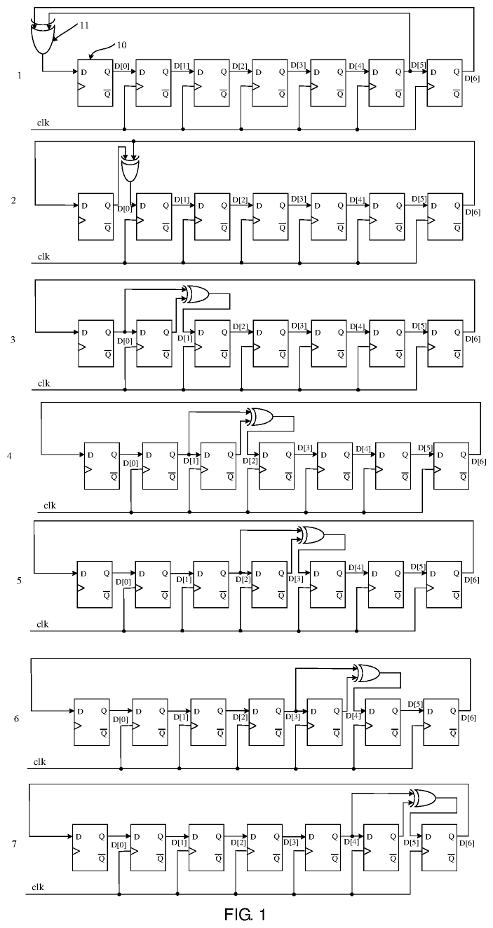

FIG. 1 shows seven different circuit structure diagrams. As shown in FIG. 1, the seven different circuit diagrams labeled 1-7 each have a different tap position. The random number generator circuit comprises: seven serially-connected flip-flops 10 which are D flip-flops, the output of the previous flip-flop 10 is used as the input of the next flip-flop 10, and each flip-flop 10 receives a driving clock signal clk; an XOR gate 11, two input terminals of the XOR gate 11 are respectively connected to the input terminal and output terminal of a flip-flop 10, and the output terminal of the XOR gate 11 is used as the input terminal of another flip-flop 10; the position of the XOR gate 11 determines the tap position of the random number generator circuit; from left to right, the flip-flops 10 are called the zeroth-stage/first-stage . . . The sixth-stage flip-flops 10, and the outputs of the flip-flops 10 are correspondingly D[0]D[1]. . . D[6].

For the circuit diagram labeled 1, the random number generator circuit generates random numbers with the first random sequence: the tap position is the zeroth-stage flip-flop 10, and the output of the random number generator circuit is arranged, according to the bit positions from high to low, as D[0]D[6]D[5]D[4]D[3]D[2]D[1].

For the circuit diagram labeled 2, the random number generator circuit generates random numbers with the second random sequence: the tap position is the first-stage flip-flop 10, and the output of the random number generator circuit is arranged, according to the bit positions from high to low, as D[1]D[0]D[6]D[5]D[4]D[3]D[2].

For the circuit diagram labeled 3, the random number generator circuit generates random numbers with the third random sequence: the tap position is the second-stage flip-flop 10, and the output of the random number generator circuit is arranged, according to the bit positions from high to low, as D[2]D[1]D[0]D[6]D[5]D[4]D[3].

For the circuit diagram labeled 4, the random number generator circuit generates random numbers with the fourth random sequence: the tap position is the third-stage flip-flop 10, and the output of the random number generator circuit is arranged, according to the bit positions from high to low, as D[3]D[2]D[1]D[0]D[6]D[5]D[4].

For the circuit diagram labeled 5, the random number generator circuit generates random numbers with the fifth random sequence: the tap position is the fourth-stage flip-flop 10, and the output of the random number generator circuit is arranged, according to the bit positions from high to low, as D[4]D[3]D[2]D[1]D[0]D[6]D[5].

For the circuit diagram labeled 6, the random number generator circuit generates random numbers with the sixth random sequence: the tap position is the fifth-stage flip-flop 10, and the output of the random number generator circuit is arranged, according to the bit positions from high to low, as D[5]D[4]D[3]D[2]D[1]D[0]D[6].

For the circuit diagram labeled 7, the random number generator circuit generates random numbers with the seventh random sequence: the tap position is the sixth-stage flip-flop 10, and the output of the random number generator circuit is arranged, according to the bit positions from high to low, as D[6]D[5]D[4]D[3]D[2]D[1]D[0].

From the above analysis, it may be found that, in order to obtain different random sequences, it is necessary to change the tap position of the circuit diagram, that is, to provide seven circuits, which increases the circuit complexity. In addition, it may be known from the above analysis that, for a circuit with a fixed bit position of a random number, the amount by which the tap position may be changed is fixed, resulting in a fixed number of variable random sequences. As shown in FIG. 1, to generate a 7-bit random number, the maximum change amount of the tap position is 7, and the maximum number of types of random sequences that may be generated is also 7. Therefore, increasing the random sequences in this way is limited.

The embodiment of the present disclosure provides a random number generator circuit, comprising a random number generator, a control signal generation module, and a multi-select module. The multi-select module may be configured to reorder the bit positions of the first random numbers generated by the random number generator, thereby increasing the random sequences of random numbers generated by the random number generator circuit, and improving the randomness of random numbers.

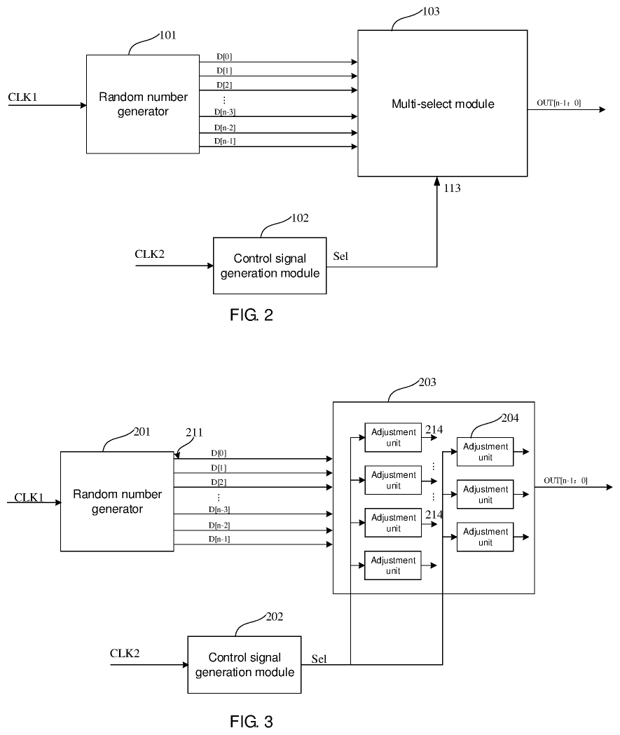

FIG. 2 is a functional block diagram of a random number generator circuit according to an embodiment of the present disclosure. Referring to FIG. 2, in this embodiment, the random number generator circuit comprises: a random number generator 101, configured to output a plurality of first random numbers in each counting cycle; a control signal generation module 102, configured to receive a trigger signal CLK2 and output control signals Sel corresponding to different first random numbers based on the trigger signal CLK2; and a multi-select module 103, configured to receive the first random number and the control signal Sel corresponding to the first random number, based on the control signal Sel to adjust at least one bit position of the first random number, obtain a second random number, and output a plurality of the second random numbers. The random number generator circuit in this embodiment will be described in detail below with reference to the accompanying drawing.

The random number generator 101 is an n-bit random number generator. Correspondingly, the plurality of first random numbers are 2ⁿ−1 first random numbers. The random number generator 101 receives a driving clock signal CLK1 to generate the first random numbers. The period in which the random number generator 101 generates all different first random numbers is an counting cycle.

The random number generator 101 has n first output terminals, and each of the first output terminals has a fixed bit position, where n is an integer greater than 1, for example 4, 7, 10, etc. The random number generator 101 may be a linear feedback shift register, and may comprise n serially-connected flip-flops, the output terminal of each flip-flop is one of the n first output terminals, and the bit position of the output terminal of each flip-flop is different.

In an example, D[0], D[1], D[2]. . . D[n-3], D[n-2], D[n-1] are used to denote the first output terminals (i e., the output terminals of the flip-flops), and the bit positions of the first output terminals may be arranged from high to low as D[0], D[n-1], D[n-2], D[n-3] D[2], D[1], where n is greater than 3. In this embodiment, the random number generator 101 may generate first random numbers with one random sequence. That is, the random number generator 101 may be a linear shift register with a fixed tap position. It may be understood that, in other embodiments, the random number generator may generate first random numbers with multiple random sequences.

The control signal generation module 102 has a trigger terminal 112 for receiving the trigger signal CLK2, and a signal output terminal 122 for outputting the control signal Sel.

In order to improve the synchronization between the control signal Sel and the output data of the first output terminal, in this embodiment, the trigger signal CLK2 is associated with the random number generator 101. In this way, the synchronization of the change of the control signal Sel when the first random number changes may be improved.

In an example, the control signal generation module 102 may be configured that the different first random numbers are first random numbers in different counting cycles; in a same counting cycle, the control signal Sel does not change; the control signal Sel corresponding to one counting cycle is different from the control signal Sel corresponding to an adjacent counting cycle. In this way, in a same counting cycle, the multi-select module 103 adjusts the bit positions of a plurality of first random numbers in a same counting cycle in the same method. That is, the method of obtaining the second random numbers based on the first random numbers is the same, which is beneficial to decrease the circuit complexity.

The trigger signal CLK2 may be a trigger driving clock signal, and the clock period of the trigger driving clock signal is the same as the counting cycle. Alternatively, the trigger signal CLK2 may be output by the random number generator 101. That is, the random number generator 101 outputs an expiration signal after a counting cycle is over. The control signal generation module 102 receives the expiration signal as the trigger signal.

In another example, the control signal generation module 102 may be configured that the different first random numbers comprise the first random numbers in each of the counting cycles, and the control signals Sel corresponding to the different first random numbers are different in a same counting cycle. In this way, since the control signals Sel are different in a single counting cycle, the multi-select module 103 may adjust the bit position of each first random number in a same counting cycle differently, which is beneficial to further increase the randomness of second random numbers. More specifically, since the control signals Sel in a same counting cycle are different, the randomness of first random numbers in a same counting cycle can be increased while increasing the randomness of first random numbers in different counting cycles.

The random number generator 101 receives the driving clock signal CLK1 to generate first random numbers, and the control signal generation module 102 receives the driving clock signal CLK1 as the trigger signal CLK2.

In this embodiment, the multi-select module 103 comprises: a chip select input terminal 113, configured to receive the control signals Sel; and a data input terminal, connected to the n first output terminals and configured to receive the first random numbers; the multi-select module 103, having N different bit position adjustment modes, and each of the bit position adjustment modes corresponding to one of the control signals, where N is an integer greater than 1; and the multi-select module 103 being further configured to adjust bit positions of data of the n first output terminals to obtain the second random numbers.

The multi-select module 103 comprises data output terminals OUT[n-1:0] which output n-bit second random numbers.

Compared with the random sequences of the first random numbers generated by the random number generator 101, the random sequences of the second random numbers output by the multi-select module 103 are increased by N times.

The number of types of the control signals Sel is greater than or equal to N, which ensures that all different bit position adjustment modes will be used to adjust the bit positions of the first random numbers, thereby increasing the random sequences of the second random numbers. Therefore, the control signal generation module 102 may be properly set according to N, to ensure that the type of the generated control signal Sel meets the requirements.

In this embodiment, N is greater than or equal to n, which is beneficial to increase the random sequences of the second random numbers. Specifically, the bit position arrangement of the data of the n first output terminals is a first bit position arrangement, the data output by the output terminals of the multi-select module 103 may have N second bit position arrangements, and each of the second bit position arrangements is obtained after adjusting the first bit position based on a bit position adjustment mode. It should be noted that, in order to retain the random sequences of the first random numbers generated by the random number generator 101, at least one second bit position arrangement is the same as the first bit position arrangement. It should also be noted that, in other embodiments, N may be 1.

In addition, in order to decrease the circuit complexity of the multi-select module 103, the multi-select module 103 may be configured that, in N second bit position arrangements, the position of the output terminals of the multi-select module 103 corresponding to data of one bit is different, and the position arrangements of the output terminals of the multi-select module 103 corresponding to data of remaining bits remains unchanged. For example, from the highest bit to the lowest bit, the first bit position arrangement is D[0], D[n-1], D[n-2]. . . D[3], D[2], D[1]; and from the highest bit to the lowest bit, the second bit position arrangement comprises multiple arrangements in Table 1.

TABLE 1

| | | | | | | | | |
|---|---|---|---|---|---|---|---|---|
| 1 | D[0] | D[n-1] | D[n-2] | D[n-3] | . . . | D[3] | D[2] | D[1] |
| 2 | D[1] | D[0] | D[n-1] | D[n-2] | . . . | D[4] | D[3] | D[2] |
| 3 | D[2] | D[1] | D[0] | D[n-1] | . . . | D[5] | D[4] | D[3] |
| . . . | . . . | . . . | . . . | . . . | . . . | . . . | . . . | . . . |
| n-1 | D[n-2] | D[n-3] | D[n-4] | D[n-5] | . . . | D[1] | D[0] | D[n] |
| n | D[n-1] | D[n-2] | D[n-3] | D[n-4] | . . . | D[2] | D[1] | D[0] |

It may be understood that, in other embodiments, the positions of the output terminals of the multi-select module 103 corresponding to the data of at least two bits may be different. For the n first output terminals, the bits of the data corresponding to each first output terminal may be changed. According to different permutations and combinations, there are a total of Cₙⁿ⁻¹ changes, that is, N≤Cₙⁿ⁻¹, i.e., N≤n×(n-1)×(n-2) . . . 2×1.

In order to decrease the complexity of the multi-select module 103, N may be the same as n.

It may be understood that, in other embodiments, N may be less than n. In this embodiment, the random number generator 101 outputs binary first random numbers, and correspondingly, the multi-select module 103 outputs binary second random numbers.

In the random number generator circuit in this embodiment, the multi-select module 103 may reorder the bits of the first random numbers, thereby generating more random sequences. In this way, the randomness of random numbers generated by the random number generator circuit is improved. In addition, compared to the use of multiple random number generators with different tap positions, the circuit structure of this embodiment is simpler and has lower power consumption.

Another embodiment of the present disclosure further provides a random number generator circuit, which is substantially the same as the foregoing embodiment, with the main difference in the more detailed description of the modules. The random number generator circuit according to another embodiment of the present disclosure will be described in detail below with reference to the accompanying drawing. For the same or corresponding parts as the foregoing embodiment, reference may be made to the foregoing embodiment and they will not be described in detail below.

FIG. 3 is a functional block diagram of a random number generator circuit according to another embodiment of the present disclosure. Referring to FIG. 3, in this embodiment, the random number generator circuit comprises: an n-bit random number generator 201 having n first output terminals 211; a control signal generation module 202; a multi-select module 203, the multi-select module 203 having a chip select input terminal and a data input terminal, the multi-select module 203 having data output terminals OUT[n-1:0].

The multi-select module 203 comprises N adjustment units 204. Each adjustment unit 204 defines a bit position adjustment mode; and each adjustment unit 204 has a data input terminal, and each adjustment unit 204 has a chip select input terminal. Each adjustment unit 204 is configured to receive a control signal Sel, and the adjustment unit 204 corresponding to the control signal Sel outputs a second random number.

That is, the output terminals of each adjustment unit 204 is the data output terminals OUT[n-1:0] of the multi-select module 203, and the control signal Sel is used as the chip select signal of the adjustment unit 204. Based on the control signal Sel, the output terminals of the corresponding adjustment unit 204 are selected as the data output terminals OUT[n-1:0] of the multi-select module 203.

According to the bit position of the respective output data, each of the n first output terminals 211 is labeled D[n-1], D[n-2]. . . D[3], D[ 2], D[1], D[0].

The bit position arrangement of the data of the n first output terminals 211 is a first bit position arrangement, for example, D[0]D[n-1]D[n-2]. . . D[3]D[2]D[1]. Each adjustment unit 204 has n second output terminals 214, and bit position arrangement of data of the n second output terminals 214 is a second bit position arrangement. The second bit position arrangements are different, and the second bit position arrangement is different from the first bit position arrangement. For example, the second bit position arrangement may be D[n-1]D[n-2]. . . D[3]D[2]D[1]D[0], etc. For detailed description of the second bit position arrangement and the first bit position arrangement, please refer to the foregoing embodiment.

In this embodiment, the number of adjustment units 204 being the same as the number of bits of the first random numbers generated by the random number generator 201 is used as an example, that is, N is the same as n. In other embodiments, the number of adjustment units may be greater or less than the number of bits of the random number generator.

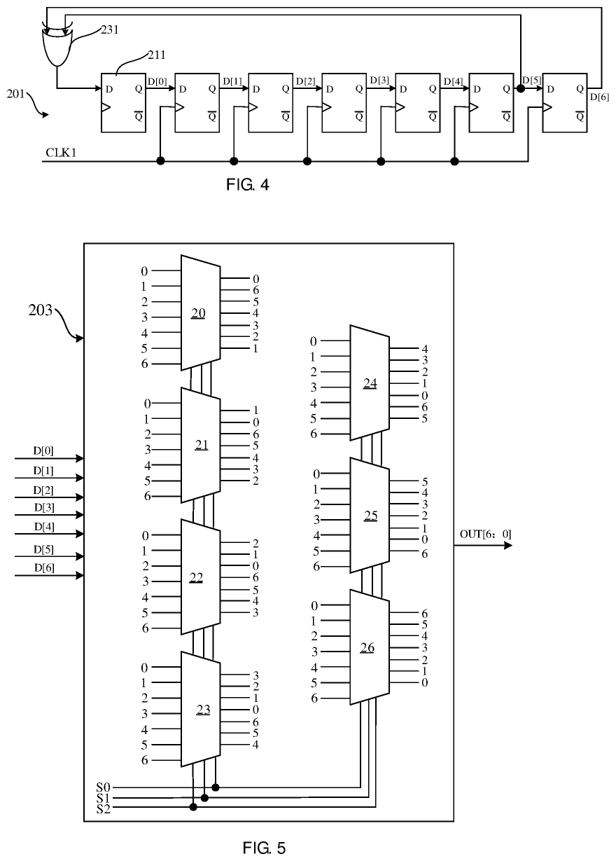

FIG. 4 is a circuit structure diagram of the random number generator 201 in this embodiment.

Referring to FIG. 4, the random number generator 201 is a linear shift register, comprising: n flip-flops 211 and an XOR gate 231. An input terminal and an output terminal of a flip-flop 211 serve as two input terminals of the XOR gate 231, and the output terminal of the XOR gate 231 is connected to the input terminal of another flip-flop 211. The position of the XOR gate 231 defines the tap position of the random number generator 201, and the output terminal of each flip-flop 211 serves as a first output terminal 211 (referring to FIG. 3).

According to the serially-connected sequence, the flip-flops 211 are sequentially denoted as a zeroth-stage flip-flop, a first-stage flip-flop, a second-stage flip-flop . . . a (n-1)th-stage flip-flop.

In this embodiment, the random number generator 201 being a 7-bit random number generator and a binary 7-bit random number generator is used as an example for detailed description. 127 first random numbers are generated in a counting cycle. In FIG. 4, the random number generator 201 has seven flip-flops 211, and the position of the XOR gate 231 determines the bit position arrangement of the data of the n first output terminals 211. For example, in FIG. 4, the bit position arrangement of the data of the seven first output terminals 211 is D[0]D[6]D[5]D[4]D[3]D[2]D[1].

It should be noted that, in other embodiments, the input terminal and output terminal of the XOR gate 231 may be connected to other flip-flops accordingly.

FIG. 5 is a schematic structure diagram of a multi-select module 203 in this embodiment, comprising seven adjustment units 204 (referring to FIG. 3). The n first output terminals 211 are used as the input terminals of each adjustment unit 204. For ease of illustration, the input terminals of each adjustment unit 204 in FIG. 5 are indicated by 0 instead of D[0], by 1 instead of D[1], and so on; and the second output terminals 214 are indicated by 0 instead of D[0] and so on. It should be noted that the data labeled D[0] is the data of the zeroth first output terminal 211, the data labeled D[1] is the data of the first output terminal 211, and so on.

In FIG. 5, for ease of description, different adjustment units 204 are labeled 20/21/22/23/24/25/26. The arrangement of the second output terminals of each adjustment unit 204 is different. As an example, according to the arrangement from top to bottom, the bit position of each data is sorted from high to low, and the data output by the second output terminals of the adjustment unit 204 labeled 20 is D[0]D[6]D[5]D[4]D[3]D[2]D[1], and the data output by the second output terminals of the adjustment unit 204 labeled 21 is D[1]D[0]D[6]D[5]D[4]D[3]D[2].

In this embodiment, the random number generator 201 has a fixed tap position, and the multi-select module 203 is configured to adjust the generated random numbers by simulating the tap position of the random number generator 201. Correspondingly, the multi-select module 203 has n different adjustment units 204. As shown in FIG. 5, the adjustment unit 204 labeled 21 is used to simulate the LFSR with the tap position of the random number generator 201 in the zeroth-stage flip-flop in FIG. 4, the adjustment unit 204 labeled 22 is used to simulate the LFSR with the tap position in the first-stage flip-flop in FIG. 4, the adjustment unit 204 labeled 23 is used to simulate the LFSR with the tap position in the second-stage flip-flop in FIG. 4, and so on.

It should be noted that, in this embodiment, as an example, the random number generator 201 is a 7-bit random number generator. In other embodiments, the random number generator may be a random number generator of any bit, for example 3-bit, 4-bit, 10-bit, 20-bit, and so on. In this embodiment, the control signal generation module 202 comprises an m-bit counter 212, where N≤2^{m}−1, m is any natural number, and N is any natural number greater than or equal to 2. Specifically, m is greater than or equal to the result obtained by rounding down IgN/Ig2+1. For example, when N is 7, m is greater than or equal to 3.

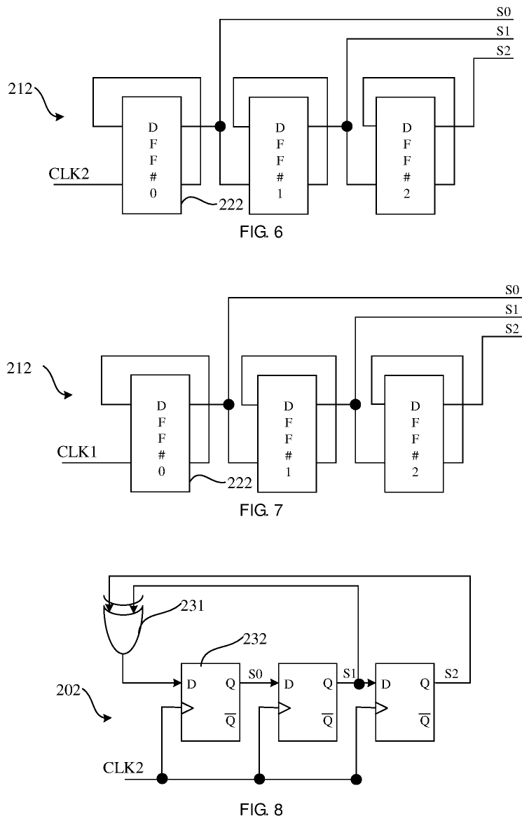

As shown in FIG. 6, the m-bit counter 212 comprises m flip-flops 222; the trigger signal CLK2 is used as the clock input signal of the fist-stage flip-flop 222, the output terminal of the flip-flop 222 in the previous stage is used as the clock input signal of the flip-flop 222 in the next stage, and the output terminals of the m flip-flops 222 collectively output the control signal Sel. In this embodiment, N is 7, and the counter 212 comprises three flip-flops 222, which are respectively labeled DFF#0, DFF#1, and DFF#2.

The random number generator 201 is further configured to output an expiration signal after each of the counting cycles is over; and the control signal generation module 202 receives the expiration signal as the trigger signal. In this way, in a same counting cycle, the control signal Sel does not change; and different counting cycles correspond to different control signals Sel.

In this embodiment, the control signal generation module 202 is a 3-bit counter having three output terminals S0/S1/S2. The control signal Sel is shown in Table 2.

TABLE 2

| S2 (Most | | S0 (Least | |
|---|---|---|---|
| Significant Bit) | S1 | Significant Bit) | Sel |
| 0 | 0 | 0 | 0 |
| 0 | 0 | 1 | 1 |
| 0 | 1 | 0 | 2 |
| 0 | 1 | 1 | 3 |
| 1 | 0 | 0 | 4 |
| 1 | 0 | 1 | 5 |
| 1 | 1 | 0 | 6 |

The working principle of the random number generator circuit in this embodiment will be described below with reference to the accompanying drawing.

In the first counting cycle, the random number generator 201 generates a plurality of first random numbers, and the control signal Sel remains unchanged at 0. The corresponding adjustment unit 204 labeled 20 in the multi-select module 203 is selected. The second output terminal 214 outputs a plurality of second random numbers. The order of the second random numbers is the same as the order of the first random numbers.

When the first counting cycle is over, the random number generator 201 outputs an expiration signal which is used as the trigger signal of the counter. S2S1S0 changes from 000 to 001 and the control signal Sel changes from 0 to 1. The corresponding adjustment unit 204 labeled 21 is selected. In the second counting cycle, the second output terminals of the adjustment unit 204 labeled 21 input a plurality of second random numbers. The order of the second random numbers is different from the order of the first random numbers.

Similarly, after each counting cycle is over, the control signal Sel output by the output terminal of the counter is the numerical value in the previous counting cycle +1. Thus, the second output terminals of another adjustment unit 204 are selected as the output terminals of the multi-select module 203.

In this way, for the seven counting cycles, the order of the second random numbers in each counting cycle has changed. There are seven random sequences of the second random numbers. Thus, the randomness of the random numbers generated by the random number generator circuit is increased.

In another example, as shown in FIG. 7, the trigger signal of the counter is the same as the driving clock signal of the random number generator 201. In each counting cycle, different first random numbers correspond to different control signals Sel. Therefore, in each counting cycle, different adjustment units 204 may be called to rearrange the bit positions. Thus, the randomness of the random numbers is further increased and more random sequences may be generated. The working principle of the random number generator circuit will be described below.

In each counting cycle, the random number generator 201 generates a first random number, the control signal Sel output by the counter is 0, and the adjustment unit 204 labeled 20 is selected to generate the second random number; the random number generator 201 generates a second random number, the control signal Sel output by the counter is 1, the adjustment unit 204 labeled 21 is selected to generate the second random number; the control signal Sel output by the counter is 2, the adjustment unit 204 labeled 22 is selected to generate a second random number; and so on. When the control signal output by the counter is 7, the counter starts counting from 0 again. It may be understood that the number of adjustment units 204 in the multi-select module 203 may be the same as the number of the first random numbers generated in each counting cycle, and the counter may be set according to the number of the adjustment circuits 204. It should be noted that the control signal Sel and the correspondingly selected adjustment unit 204 are only examples, as long as different adjustment units 204 are correspondingly selected for different control signals Sel.

In another example, as shown in FIG. 8, the control signal generation module 202 comprises an M-bit pseudo-random number generator circuit, and the pseudo-random number generator circuit and the random number generator 201 receive a same driving clock signal CLK. Compared with the counter, the control signal output by the pseudo-random number generator circuit is more random, so the adjustment units 204 corresponding to different first random numbers are more random.

The pseudo-random number generator circuit comprises M D flip-flops 232 and a first XOR gate 231. The pseudo-random number generator circuit has output terminals S0/S1/S2, and the signal at the output terminals is used as a control signal.

The random number generator circuit in this embodiment can generate, by using a random number generator 201 with a fixed random sequence, random numbers with N different random sequences. The security of using the random number generator circuit is improved.

Those skilled in the art will readily think of other implementations of the present disclosure by considering the specification and practicing the disclosure disclosed herein. The present disclosure is intended to encompass any variations, uses, or adaptive changes of the present disclosure. These variations, uses, or adaptive changes follow the general principles of the present disclosure and include common knowledge or conventional technical means in the technical field that are not disclosed in the present disclosure. The specification and the embodiments are just exemplary, and the true scope and spirit of the present disclosure are defined by the appended claims.

It should be understood that the present disclosure is not limited to the precise structures that have been described above and shown in the drawings, and various modifications and changes may be made without departing from its scope. The scope of the present disclosure is defined only by the appended claims.

### INDUSTRIAL APPLICABILITY

The random number generator circuit according to the present disclosure has a simple structure and low power consumption. At least one bit position of a plurality of first random numbers output by the random number generator is reordered by a multi-select module to obtain second random numbers, thereby increasing the random sequences of random numbers generated by the random number generator circuit. More random sequences are generated and the randomness of random numbers is improved.

1. A random number generator circuit, comprising:
a random number generator, configured to output a plurality of first random numbers in each counting cycle;
a control signal generation module, configured to receive a trigger signal and output control signals corresponding to different first random numbers based on the trigger signal; and
a multi-select module, configured to receive the first random number and the control signal corresponding to the first random number, based on the control signal to adjust at least one bit position of the first random number, obtain a second random number, and output a plurality of the second random numbers.

2. The random number generator circuit according to claim 1, wherein the random number generator is an n-bit random number generator, and the plurality of first random numbers are 2ⁿ−1 first random numbers; and the random number generator has n first output terminals, and each of the first output terminals has a fixed bit position, where n is an integer greater than 1.

3. The random number generator circuit according to claim 2, wherein the multi-select module comprises:
a chip select input terminal, configured to receive the control signals; and
a data input terminal, connected to the n first output terminals and configured to receive the first random numbers;
the multi-select module, having N different bit position adjustment modes, and each of the bit position adjustment modes corresponding to one of the control signals, where N is an integer greater than or equal to 1; and the multi-select module being further configured to adjust bit positions of data of the n first output terminals to obtain the second random numbers.

4. The random number generator circuit according to claim 3, wherein the multi-select module comprises N adjustment units, and each of the adjustment units defines a bit position adjustment mode; and each of the adjustment units has the data input terminal, and each of the adjustment units has the chip select input terminal.

5. The random number generator circuit according to claim 4, wherein a bit position arrangement of the data of the n first output terminals is a first bit position arrangement, each of the adjustment units has n second output terminals, and bit position arrangement of data of the n second output terminals is a second bit position arrangement; and each of the second bit position arrangements is different, and the second bit position arrangement is different from the first bit position arrangement.

6. The random number generator circuit according to claim 5, wherein the N adjustment units are configured that, in N second bit position arrangements, a position of the second output terminals corresponding to data of one bit is different, and the position arrangements of the second output terminals corresponding to data of remaining bits remains unchanged.

7. The random number generator circuit according to claim 5, wherein at least one of the second bit position arrangements is the same as the first bit position arrangement.

8. The random number generator circuit according to claim 4, wherein the N is greater than or equal to n.

9. The random number generator circuit according to claim 3, wherein the control signal generation module comprises an m-bit counter, where N≤2^{m}−1, m is any natural number, and N is any natural number greater than or equal to 2.

10. The random number generator circuit according to claim 1, wherein the control signal generation module is further configured that the different first random numbers are first random numbers in the-different counting cycles; in a same counting cycle, the control signal does not change; a control signal corresponding to one counting cycle is different from a control signal corresponding to an adjacent counting cycle.

11. The random number generator circuit according to claim 10, wherein the random number generator is further configured to output an expiration signal after each of the counting cycles is over; and the control signal generation module receives the expiration signal as the trigger signal.

12. The random number generator circuit according to claim 1, wherein the control signal generation module is further configured that the different first random numbers comprise the first random numbers in each of the counting cycles, and the control signals corresponding to the different first random numbers are different in a same counting cycle.

13. The random number generator circuit according to claim 12, wherein the random number generator is further configured to receive a driving clock signal to generate the first random numbers, and the control signal generation module is further configured to receive the driving clock signal as the trigger signal.

14. The random number generator circuit according to claim 1, wherein the control signal generation module comprises an M-bit pseudo-random number generator circuit, and the pseudo-random number generator circuit and the random number generator receive a same driving clock signal.

15. The random number generator circuit according to claim 1, wherein the random number generator comprises a linear feedback shift register.
